(19) United States
(12) Patent Application Publication
(10) Pub. No.: US 2026/0135540 A1
(43) Pub. Date: May 14, 2026

(54) ACOUSTIC WAVE DEVICE

(71) Applicant: Murata Manufacturing Co., Ltd., Nagaokakyo-shi (JP)

(72) Inventors: Masaaki MATSUMORI, Nagaokakyo-shi (JP); Takahiro TSUTAYA, Nagaokakyo-shi (JP); Hiroshi SOMADA, Nagaokakyo-shi (JP)

(21) Appl. No.: 19/442,070

(22) Filed: Jan. 7, 2026

Related U.S. Application Data
(63) Continuation of application No. PCT/JP2024/027429, filed on Jul. 31, 2024.

(30) Foreign Application Priority Data
Aug. 9, 2023 (JP) 2023-129698

(51) Int. Cl. H03H 9/15; H03H 9/13

(52) U.S. Cl. CPC H03H 9/15; H03H 9/131

(57) ABSTRACT

An acoustic wave device includes a substrate including first and second main surfaces facing away from each other, a substrate including a third main surface facing the first main surface, a functional electrode on the third main surface, a support portion positioned between the main surface and the main surface to provide a space between the first and third main surfaces, and a via conductor in the substrate and extending from the first main surface toward the second main surface. The support portion includes a first metal film on the first main surface and a second metal film on the third main surface, and a ratio of an area of the first metal film to that of the first main surface is larger than a ratio of an area of the second metal film to that of the third main surface.

### CROSS REFERENCE TO RELATED APPLICATIONS

This application claims the benefit of priority to Japanese Patent Application No. 2023-129698 filed on Aug. 9, 2023 and is a Continuation application of PCT Application No. PCT/JP2024/027429 filed on Jul. 31, 2024. The entire contents of each application are hereby incorporated herein by reference.

### BACKGROUND OF THE INVENTION

### 1. Field of the Invention

The present invention relates to acoustic wave devices.

### 2. Description of the Related Art

Japanese Unexamined Patent Application Publication No. 2018-137742 discloses an electronic device including a piezoelectric thin-film resonator, a first substrate (piezoelectricity substrate) on which the piezoelectric thin-film resonator is disposed, a second substrate (lid substrate) disposed to sandwich the piezoelectric thin-film resonator between the first substrate and the second substrate, a thin film of a high resistivity material provided on the second substrate, and a via conductor provided in the first substrate. According to this, signals from the piezoelectric thin-film resonator can be input and output from a first substrate side while the signals are reduced or prevented from being coupled to the second substrate.

When the via conductor is configured as a structure to input and output signals of the piezoelectric thin-film resonator (acoustic wave resonator) by machining the substrate made of a piezoelectric material, degradation of signals of the acoustic wave resonator is a concern. On the other hand, a structure to input and output signals of the acoustic wave resonator by providing the via conductor in the lid substrate may be used, but degradation of signals of the acoustic wave resonator needs to be further reduced or prevented.

### SUMMARY OF THE INVENTION

Example embodiments of the present invention provide acoustic wave devices in each of which degradation of signals of an acoustic wave resonator is reduced or prevented.

According to an example embodiment of the present invention, an acoustic wave device includes a first substrate including a first main surface and a second main surface facing away from each other, a second substrate including a third main surface facing the first main surface, a functional electrode on the third main surface, a support portion between the first main surface and the third main surface to provide a space between the first main surface and the third main surface, and a via conductor in the first substrate and extending from the first main surface toward the second main surface, in which the support portion includes a first metal film on the first main surface, and a second metal film on the third main surface and connected to the functional electrode, and, in plan view of the first main surface and the third main surface, a ratio of an area of the first metal film to an area of the first main surface is larger than a ratio of an area of the second metal film to an area of the third main surface.

According to another example embodiment of the present invention, an acoustic wave device includes a first substrate including a first main surface and a second main surface facing away from each other, a second substrate including a third main surface facing the first main surface, a functional electrode on the third main surface, a support portion between the first main surface and the third main surface to provide a space between the first main surface and the third main surface, and a via conductor in the first substrate and extending from the first main surface toward the second main surface, in which the support portion includes a first metal film on the first main surface, and a second metal film on the third main surface and connected to the functional electrode, the first metal film is connected to a ground through the via conductor, in plan view of the first main surface and the third main surface, the first metal film overlaps at least a portion of the functional electrode.

According to example embodiments of the present invention, acoustic wave devices in each of which degradation of signals of an acoustic wave resonator is reduced or prevent are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a cross-sectional view of an acoustic wave device according to an example embodiment of the present invention.

FIG. 2A is a first plan view of an acoustic wave device according to an example embodiment of the present invention.

FIG. 2B is a second plan view of an acoustic wave device according to an example embodiment of the present invention.

FIG. 2C is a third plan view of an acoustic wave device according to an example embodiment of the present invention.

FIG. 3A indicates a plan view and a cross-sectional view schematically illustrating a first example of an acoustic wave resonator of an acoustic wave device according to an example embodiment of the present invention.

FIG. 3B is a cross-sectional view schematically illustrating a second example of an acoustic wave resonator of an acoustic wave device according to an example embodiment of the present invention.

FIG. 3C is a cross-sectional schematically illustrating a third example of an acoustic wave resonator of an acoustic wave device according to an example embodiment of the present invention.

FIG. 3D is a cross-sectional view schematically illustrating a fourth example of an acoustic wave resonator of an acoustic wave device according to an example embodiment of the present invention.

FIG. 4 is a cross-sectional view illustrating a support portion of an acoustic wave device according to an example embodiment and surroundings thereof in an enlarged manner.

FIG. 5 is a cross-sectional view illustrating an example of a multilayer structure of metal films of an acoustic wave device according to an example embodiment of the present invention.

FIG. 6A is a cross-sectional view of an inner support portion according to an example embodiment of the present invention.

FIG. 6B is a cross-sectional view of an outer support portion according to an example embodiment of the present invention.

FIG. 7 is a cross-sectional view illustrating a via conductor of an acoustic wave device according to an example embodiment and surroundings thereof in an enlarged manner.

FIG. 8A is a schematic cross-sectional view illustrating an interface between a via conductor and a first substrate of an acoustic wave device according to an example embodiment of the present invention.

FIG. 8B illustrates a SEM image of an interface between a via conductor and a first substrate of an acoustic wave device according to an example embodiment of the present invention.

FIG. 9 is a cross-sectional view of a planar electrode disposed at an opening portion of a via conductor of an acoustic wave device according to an example embodiment of the present invention.

FIG. 10A is a first plan view of an acoustic wave device according to modification 1 of an example embodiment of the present invention.

FIG. 10B is a second plan view of an acoustic wave device according to modification 1 of an example embodiment of the present invention.

FIG. 10C is a third plan view of an acoustic wave device according to modification 1 of an example embodiment of the present invention.

FIG. 11A is a first plan view of an acoustic wave device according to modification 2 of an example embodiment of the present invention.

FIG. 11B is a second plan view of an acoustic wave device according to modification 2 of an example embodiment of the present invention.

FIG. 11C a third plan view of an acoustic wave device according to modification 2 of an example embodiment of the present invention.

FIG. 12 is a cross-sectional view of an acoustic wave device according to modification 3 of an example embodiment of the present invention.

FIG. 13 is a first plan view of an acoustic wave device according to modification 3 of an example embodiment of the present invention.

FIG. 14 is a cross-sectional view of an acoustic wave device according to modification 4 of an example embodiment of the present invention.

### DETAILED DESCRIPTION OF THE EXAMPLE EMBODIMENTS

Example embodiments of the present invention will be described in detail below with reference to the drawings. The example embodiments described below illustrate comprehensive or specific examples. The numerical values, shapes, materials, components, arrangement and connection configurations of components illustrated in the example embodiments below are examples and are not intended to limit the present invention. Of components in the following example embodiments, components not described in independent claims are described as optional components. In addition, sizes or size ratios of components illustrated in the drawings are not necessarily accurate.

The drawings are schematic diagrams in which emphasis, omission, or adjustment of proportions have been performed as appropriate to describe example embodiments of the present invention and are not necessarily illustrated accurately, and the drawings do not necessarily represent actual shapes, positional relationships, and proportions. In the drawings, the same reference numerals are assigned to the same or substantially the same components, and redundant descriptions may be omitted or simplified.

In the circuit structure of example embodiments of the present invention, “connected” refers not only to direct connection between electrodes and/or wiring conductors but also to electric connection through matching elements, such as an inductor and a capacitor, and switch circuits, for example. “Connected between A and B” means connection to both A and B between A and B.

In addition, terms that indicate the relationships between elements, such as “parallel,” “orthogonal,” “normal,” and “vertical,” terms that indicate the shapes of elements, such as “rectangular”, and numerical ranges do not only represent strict meanings but also represent substantially equivalent ranges, for example, ranges including an error of approximately a few percent.

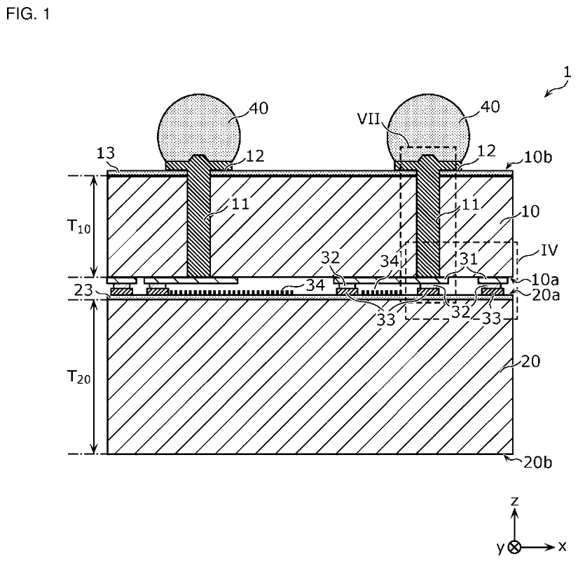

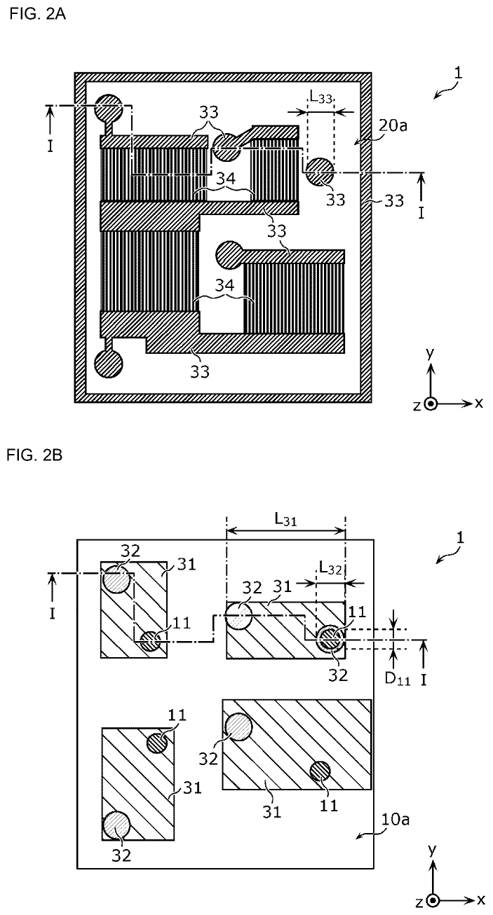

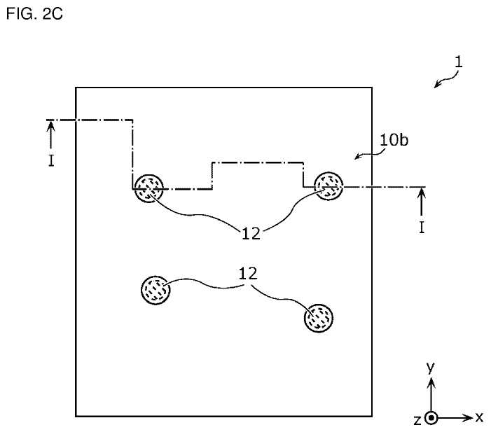

FIG. 1 is a cross-sectional view of an acoustic wave device 1 according to an example embodiment of the present invention. FIG. 2A is a first plan view of the acoustic wave device 1 according to the present example embodiment. FIG. 2B is a second plan view of the acoustic wave device 1 according to the present example embodiment. FIG. 2C is a third plan view of the acoustic wave device 1 according to the present example embodiment. FIG. 2A is a plan view (transparent view) of a main surface 20a of a substrate 20 as viewed from a Z-axis positive side, FIG. 2B is a plan view (transparent view) of a main surface 10a of a substrate 10 as viewed from the Z-axis positive side, and FIG. 2C is a plan view of a main surface 10b of the substrate 10 as viewed from the Z-axis positive side. FIG. 1 is a cross-sectional view taken along line I-I in FIGS. 2A, 2B, and 2C.

As illustrated in FIGS. 1 to 2C, the acoustic wave device 1 includes the substrates 10 and 20, metal films 31, 32, and 33, functional electrodes 34, via conductors 11, insulation films 13 and 23, planar electrodes 12, and bump electrodes 40.

The substrate 10 is an example of the first substrate and includes a main surface 10a (first main surface) and a main surface 10b (second main surface) that face away from each other. In the present example embodiment, the substrate 10 includes silicon, for example.

The substrate 20 is an example of the second substrate and includes a main surface 20a (third main surface) and a main surface 20b that face away from each other. The main surface 10a and the main surface 20a face each other. In the present example embodiment, the substrate 20 has piezoelectricity.

As illustrated in FIG. 1, the via conductors 11 are electrodes disposed in the substrate 10 to extend from the main surface 10a toward the main surface 10b. In the present example embodiment, the via conductors 11 are through-electrodes that fill cavities passing through the substrate 10 between the main surface 10a and the main surface 10b. The via conductors 11 include metal elements including, for example, copper (Cu) as a main component.

The via conductor 11 does not need to be a single via conductor that extends from the main surface 10a to the main surface 10b and may have a structure in which a plurality of via conductors are connected to each other through a planar electrode provided in the substrate 10.

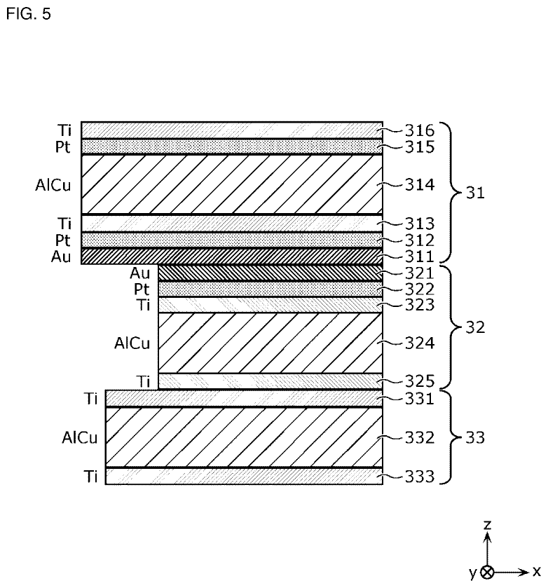

The metal film 31 is an example of the first metal film and is a planar electrode, in contact with the via conductor 11, that is disposed on the main surface 10a as illustrated in FIGS. 1 and 2B. The metal film 31 is, for example, a multilayer body including a plurality of metal layers. A specific example of the multilayer structure of the metal film 31 will be described in FIG. 5.

The metal film 32 is an example of the third metal film, and is a planar electrode in contact with the metal film 31 and disposed on the opposite side of the metal film 31 from the via conductor 11 as illustrated in FIGS. 1 and 2B. The metal film 32 is, for example, a multilayer body including a plurality of metal layers. A specific example of the multilayer structure of the metal film 32 will be described in FIG. 5.

The metal film 33 is an example of the second metal film and is a planar electrode that is disposed on the main surface 20a, connected to the functional electrode 34, and in contact with the metal film 32 as illustrated in FIGS. 1 and 2A. The metal film 33 is, for example, a multilayer body including a plurality of metal layers. A specific example of the multilayer structure of the metal film 33 will be described in FIG. 5.

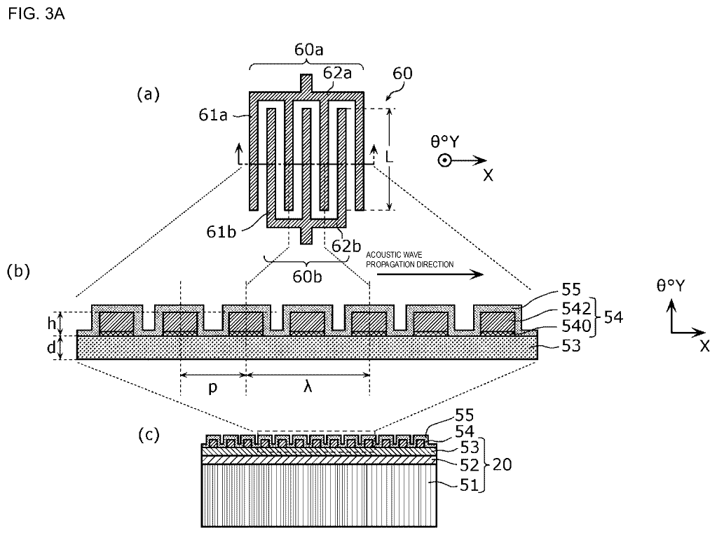

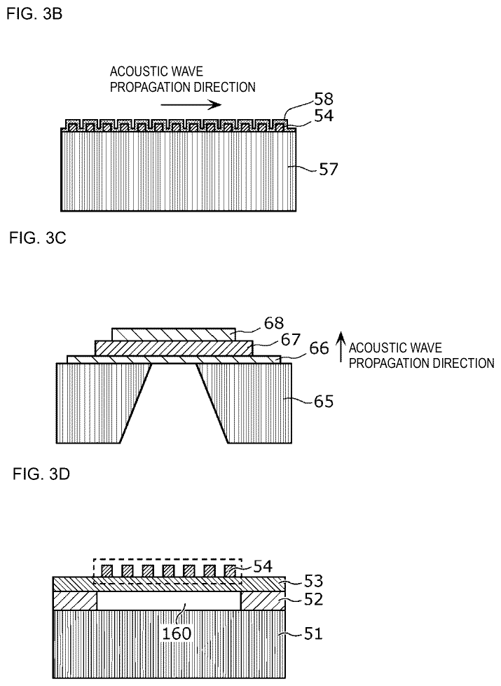

The functional electrode 34 is disposed on the main surface 20a and performs electromechanical transduction together with the substrate 20. Examples of the structures of the functional electrode 34 and the metal film 33 will be described in FIGS. 3A to 3D.

As illustrated in FIG. 1, the metal films 31, 32, and 33 define a support portion and are laminated and disposed in this order between the main surface 10a and the main surface 20a so as to provide a space between the main surface 10a and the main surface 20a.

The insulation film 13 is disposed on the main surface 10b and is, for example, a silicon oxide film. The insulation film 23 is disposed on the main surface 20a and is, for example, a silicon oxide film. At least one of the insulation films 13 and 23 may be absent.

Next, examples of the structures of the substrate 20, the functional electrode 34, and the metal films 33 will be described. FIG. 3A indicates a plan view and a cross-sectional view schematically illustrating a first example of an acoustic wave resonator 60 of the acoustic wave device 1 according to the present example embodiment. The basic structure of the acoustic wave resonator 60 of the acoustic wave device 1 is illustrated in FIG. 3A. The acoustic wave resonator 60 illustrated in FIG. 3A is intended to describe the typical structure of the acoustic wave resonator of the acoustic wave device 1, and the number and the length of the electrode fingers that define the electrodes are not limited to this example.

The acoustic wave resonator 60 includes the substrate 20 and interdigitated electrodes 60a and 60b.

As illustrated in part (a) of FIG. 3A, a pair of interdigitated electrodes 60a and 60b that face each other is provided on the substrate 20. The interdigitated electrode 60a includes a plurality of electrode fingers 61a (first electrode fingers) that are parallel to each other and a busbar electrode 62a (first busbar electrode) that connects one end of each of the plurality of electrode fingers 61a to each other. In addition, the interdigitated electrode 60b includes a plurality of electrode fingers 61b (second electrode fingers) that are parallel to each other and a busbar electrode 62b (second busbar electrode) that connects one end of each of the plurality of electrode fingers 61b to each other. The plurality of electrode fingers 61a and 61b are arranged in a direction orthogonal to the propagation direction (X-axis direction) of an acoustic wave. The busbar electrode 62a and the busbar electrode 62b are disposed to face each other with the electrode fingers 61a and 61b therebetween. The interdigitated electrodes 60a and 60b define an IDT (interdigital transducer) electrode 54.

Here, when the acoustic wave device 1 according to the present example embodiment performs electromechanical transduction by using the IDT electrode 54, the functional electrodes 34 illustrated in FIGS. 1 and 2A include the plurality of electrode fingers 61a and the plurality of electrode fingers 61b. In addition, the metal films 33 illustrated in FIGS. 1 and 2A include the busbar electrodes 62a and 62b.

The acoustic wave resonator 60 may include reflectors at both ends of the IDT electrode 54 in the propagation direction (X-axis direction) of an acoustic wave.

As illustrated in part (b) of FIG. 3A, the IDT electrode 54 has a multilayer structure including, for example, close contact layers 540 and main electrode layers 542.

The close contact layer 540 is a layer to improve the adhesion between the substrate 20 and the main electrode layer 542, and the material thereof is, for example, Ti. The material of the main electrode layer 542 is, for example, Al including about 1% Cu. The protective layer 55 covers the interdigitated electrodes 60a and 60b. The protective layer 55 protects the main electrode layers 542 from the external environment, adjusts the frequency-temperature characteristics, and improves moisture resistance, and the protective layer 55 is a dielectric film including, for example, silicon dioxide as a main component.

The materials of the close contact layers 540, the main electrode layers 542, and the protective layer 55 are not limited to the materials described above. In addition, the IDT electrode 54 does not need to have the multilayer structure described above. The IDT electrode 54 may be made of a metal, such as, for example, Ti, Al, Cu, Pt, Au, Ag, or Pd or may include a plurality of multilayer bodies made of any of the metals or alloys thereof. In addition, the protective layer 55 is not necessarily provided.

Next, the multilayer structure of the substrate 20 will be described.

As illustrated in part (c) of FIG. 3A, the substrate 20 includes a support substrate 51, an intermediate layer 52, and a piezoelectric film 53, and has a structure in which the support substrate 51, the intermediate layer 52, and the piezoelectric film 53 are laminated together in this order.

The piezoelectric film 53 is made of, for example, a θ° Y-cut X-propagating LiTaO₃ piezoelectric single crystal or piezoelectric ceramic (a lithium tantalate single crystal or ceramic cut in a plane normal to the axis rotated θ° from the Y-axis with the X-axis as the central axis in which a surface acoustic wave propagates in the X-axis direction). The material and the cut angle θ of a piezoelectric single crystal used as the piezoelectric film 53 are selected as appropriate in accordance with the required specification of each filter.

The support substrate 51 supports the intermediate layer 52, the piezoelectric film 53, and the IDT electrode 54. The support substrate 51 may also be a substrate in which the acoustic velocity of a bulk wave in the support substrate 51 is higher than the acoustic velocity of an acoustic wave, such as a surface acoustic wave or a boundary acoustic wave propagating through the piezoelectric film 53, and the support substrate 51 defines and functions so as to confine the surface acoustic wave in a portion in which the piezoelectric film 53 and the intermediate layer 52 are laminated and to prevent the surface acoustic wave from leaking below the support substrate 51. The material of the support substrate 51 can be a piezoelectric body such as, for example, aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or sialon, a dielectric such as aluminum oxide, silicon oxynitride, diamond-like carbon (DLC), or diamond, or a semiconductor such as silicon, or a material including one of the materials described above as a main component. The spinel described above includes, for example, an aluminum compound including oxygen and one or more of Mg, Fe, Zn, or Mn. Examples of the spinel described above can be MgAl₂O₄, FeAl₂O₄, ZnAl₂O₄, or MnAl₂O₄.

The intermediate layer 52 is, for example, a film in which the acoustic velocity of a bulk wave in the intermediate layer 52 is lower than the acoustic velocity of a bulk wave propagating through the piezoelectric film 53, and the intermediate layer 52 is disposed between the piezoelectric film 53 and the support substrate 51. This structure and the property that energy concentrates in a medium with essentially low acoustic velocity reduce or prevent the leakage of surface acoustic wave energy to the outside of the IDT electrode. The material of the intermediate layer 52 can be, for example, a dielectric such as glass, silicon oxide, silicon nitride, lithium oxide, tantalum oxide, or a compound in which fluorine, carbon, or boron is added to silicon oxide or a material including one of the materials described above as the main component can be used.

In the multilayer structure of the substrate 20, the Q value at the resonant frequency and the anti-resonant frequency can be made greater than that in the conventional structure in which a piezoelectric substrate is used as a single layer. That is, an acoustic wave resonator with a high Q value can be configured, and accordingly, a filter with low insertion loss can be configured by using this acoustic wave resonator.

The support substrate 51 may have a structure in which the support substrate and a high-velocity film in which the acoustic velocity of a propagating bulk wave is higher than the acoustic velocity of an acoustic wave, such as a surface acoustic wave and a boundary acoustic wave propagating through the piezoelectric film 53, are laminated together. In this case, the same material as the support substrate 51 can be used as the material of the high-velocity film. In addition, the material of the support substrate can be a piezoelectric body such as, for example, aluminum nitride, lithium tantalate, lithium niobate, or quartz, a ceramic such as alumina, sapphire, magnesia, silicon nitride, silicon carbide, zirconia, cordierite, mullite, steatite, or forsterite, a dielectric such as diamond or glass, or a semiconductor such as silicon or gallium nitride, a resin, or a material containing one of the materials described above as a main component.

The wavelength λ of the acoustic wave resonator 60 is defined by the repeating period of the plurality of electrode fingers 61a or 61b defining the IDT electrode 54 illustrated in part (b) of FIG. 3A. In addition, the electrode finger pitch p is about ½ of the wavelength λ and is defined as (W+G) where W is the line width of the electrode fingers 61a and 61b that define the interdigitated electrodes 60a and 60b, and G is the space width between adjacent electrode fingers 61a and 61b. In addition, the electrode finger duty D of the IDT electrode 54, which is the line width occupancy ratio of the electrode fingers 61a and 61b and is the ratio of the line width W to the sum of the line width W and the space width G, is defined as W/(W+G). When the spacing between adjacent electrode fingers is not constant in the IDT electrode 54, the electrode finger pitch p of the IDT electrode 54 is defined by the average electrode finger pitch p_{AVE} of the IDT electrode 54. The average electrode finger pitch p_{AVE} of the IDT electrode 54 is defined as Di/(Ni−1) where Ni is the total number of electrode fingers 61a and 61b included in the IDT 54, and Di is the center-to-center distance between the electrode finger located at one end and the electrode finger located at the other end in the propagation direction of an acoustic wave in the IDT electrode 54. In addition, when the electrode finger duty D is not constant in the IDT electrode 54, the electrode finger duty D of the IDT electrode 54 is defined by the average electrode finger duty D_{AVE} of the IDT electrode 54. The average electrode finger duty D_{AVE} Of the IDT electrode 54 is defined as W_{ALL}/(W_{ALL}+G_{ALL}) where Ni is the total number of electrode fingers 61a and 61b included in the IDT electrode 54, W_{ALL} is the total line width obtained by adding the line widths W of (Ni−1) electrode fingers to each other, and G_{ALL} is the total space width obtained by adding the space widths G of (Ni−1) spaces included in the IDT electrode 54.

The electrode finger pitch p of the interdigitated electrode of the IDT electrode 54 can be measured, for example, by measuring the line width W and the space width G by observing, in plan view, the main surface of the substrate on which the interdigitated electrode of the IDT electrode 54 is provided and/or by observing, in cross-sectional view, a cross-section in a direction orthogonal to the extension direction of the electrode finger using a scanning electron microscope (SEM), a scanning transmission electron microscope (STEM), or a transmission electron microscope (TEM).

The term “main component of a material” in this specification refers to a component that accounts for more than 50 weight percent of the material. The main component described above may exist in any of a single-crystal state, a polycrystal state, and an amorphous state, or a state in which these are mixed.

FIG. 3B is a cross-sectional view schematically illustrating a second example of an acoustic wave resonator 60 of the acoustic wave device 1 according to the present example embodiment. An example in which the IDT electrode 54 is provided on the substrate 20 that includes the piezoelectric film 53 in the acoustic wave resonator 60 is illustrated in FIG. 3A, but the substrate on which the IDT electrode 54 is provided may also be a piezoelectric single-crystal substrate 57 including a single piezoelectric layer as illustrated in FIG. 3B.

The piezoelectric single-crystal substrate 57 includes, for example, a piezoelectric single crystal of LiNbO₃. The acoustic wave resonator according to the present example includes the piezoelectric single-crystal substrate 57 of LiNbO₃, the IDT electrode 54, and a protective layer 58 provided on the piezoelectric single-crystal substrate 57 and the IDT electrode 54.

The multilayer structures, the materials, the cut angles, and the thicknesses of the piezoelectric film 53 and the piezoelectric single-crystal substrate 57 may be changed as appropriate in accordance with the required bandpass characteristics of the acoustic wave device 1. Even an acoustic wave resonator including, for example, a LiTaO₃ piezoelectric substrate having a cut-angle other than the cut-angle described above can achieve advantageous effects the same as or similar to those of the acoustic wave resonator 60 that includes the piezoelectric film 53 described above.

In addition, a piezoelectric substrate on which the IDT electrode 54 is provided may have a structure in which the support substrate, the energy confinement layer, and the piezoelectric film are laminated together in this order. The IDT electrode 54 is provided on the piezoelectric film. For example, a LiTaO₃ piezoelectric single crystal or piezoelectric ceramic is used as the piezoelectric film. The support substrate supports the piezoelectric film, the energy confinement layer, and the IDT electrode 54.

The energy confinement layer includes one or more layers, and the velocity of a bulk acoustic wave propagating through at least one of these layers is greater than the velocity of an acoustic wave propagating through the vicinity of the piezoelectric film. For example, the energy confinement layer may have a multilayer structure including a low-velocity layer and a high-velocity layer. The low-velocity layer is a film in which the acoustic velocity of a bulk wave in the low-velocity layer is smaller than the acoustic velocity of an acoustic wave propagating through the piezoelectric film. The high-velocity layer is a film in which the acoustic velocity of a bulk wave in the high-velocity layer is greater than the acoustic velocity of an acoustic wave propagating through the piezoelectric film. The support substrate may also be the high-velocity layer, for example.

In addition, the energy confinement layer may be an acoustic impedance layer having a structure in which a low-acoustic-impedance layer with relatively low acoustic impedance and a high-acoustic-impedance layer with relatively high acoustic impedance are alternately laminated together.

In addition, FIG. 3C is a cross-sectional view schematically illustrating a third example of an acoustic wave resonator 60 of the acoustic wave device 1 according to the present example embodiment. In FIG. 3C, a bulk acoustic wave resonator is illustrated as the acoustic wave resonator of the acoustic wave device 1. As illustrated in FIG. 3C, the bulk acoustic wave resonator includes, for example, a support substrate 65, a lower electrode 66, a piezoelectric layer 67, and an upper electrode 68 and has a structure in which the support substrate 65, the lower electrode 66, the piezoelectric layer 67, and the upper electrode 68 are laminated together in this order.

The support substrate 65 supports the lower electrode 66, the piezoelectric layer 67, and the upper electrode 68 and is, for example, a silicon substrate. The support substrate 65 includes a cavity in a region in contact with the lower electrode 66. As a result, the piezoelectric layer 67 can vibrate freely.

The lower electrode 66 is an example of the first planar electrode and is provided on one surface of the support substrate 65. The upper electrode 68 is an example of the second planar electrode and is provided on one surface of the support substrate 65. The lower electrode 66 and the upper electrode 68 are made of, for example, Al including about 1% Cu.

The piezoelectric layer 67 is an example of a piezoelectric thin film and is provided between the lower electrode 66 and the upper electrode 68. The piezoelectric layer 67 includes at least one of, for example, Zno (zinc oxide), AlN (aluminum nitride), PZT (lead zirconate titanate), KN (potassium niobate), LN (lithium niobate), LT (lithium tantalate), quartz, or LiBO (lithium borate) as a main component.

The bulk acoustic wave resonator having the multilayer structure described above generates resonance by applying electrical energy between the lower electrode 66 and the upper electrode 68 and inducing a bulk acoustic wave in the piezoelectric layer 67. The bulk acoustic wave generated by the bulk acoustic wave resonator propagates between the lower electrode 66 and the upper electrode 68 in a direction orthogonal to the film surface of the piezoelectric layer 67. That is, the bulk acoustic wave resonator is a resonator that utilizes a bulk acoustic wave.

Here, when the acoustic wave device 1 according to the present example embodiment performs electromechanical transduction by using a bulk acoustic wave, the functional electrode 34 illustrated in FIGS. 1 and 2A includes the lower electrode 66, the piezoelectric layer 67, and the upper electrode 68. In addition, the metal films 33 illustrated in FIGS. 1 and 2A include the lower electrode 66 and the upper electrode 68. In addition, the substrate 20 illustrated in FIGS. 1 and 2A may include the support substrate 65 without having piezoelectricity.

FIG. 3D is a cross-sectional view schematically illustrating a fourth example of an acoustic wave resonator 60 of the acoustic wave device 1 according to the present example embodiment. In the acoustic wave device 1 according to the fourth example, the substrate 20 includes the support substrate 51, the intermediate layer 52, a void 160, and a piezoelectric film 53.

In the acoustic wave device 1 according to the present example, in plan view of the main surface 20a, the void 160 is provided between the piezoelectric film 53 and the support substrate 51 in the region that overlaps the IDT electrode 54. In addition, the normalized film thickness d/p of the piezoelectric film 53 is, for example, about 0.5 or less where d is the thickness of the piezoelectric film 53 (in the Z-axis direction), and p is the electrode finger pitch of the IDT electrode 54.

Since the normalized film thickness d/p of the piezoelectric film 53 is, for example, about 0.5 or less, and the void 160 is provided, the acoustic wave resonator 60 defines a laterally excited bulk acoustic resonator (XBAR). Since the normalized film thickness d/p of the piezoelectric film 53 is, for example, about 0.5 or less, the fractional band width of the acoustic wave resonator 60 can be increased, and a resonator with a high electromechanical coupling coefficient can be provided.

The normalized film thickness d/p of the piezoelectric film 53 is, for example, more preferably about 0.24 or less. As a result, the fractional band width of the acoustic wave resonator 60 can be about 7% or more.

The electrode finger duty D and the normalized film thickness d/p of the IDT electrode 54 preferably satisfy the relationship defined by formula 1:

$$D \leq 1.75 ( d / p ) + 0.075 \qquad ( Formula 1 )$$

As a result, the spurious response of the high-order mode of the XBAR can be effectively reduced. Specifically, the fractional band width (the value obtained by dividing the differential frequency between the anti-resonant frequency and the resonant frequency by the average frequency of the anti-resonant frequency and the resonant frequency) of the XBAR can be, for example, about 17% or less, and inclusion of the spurious response of the higher-order mode within the pass band can be reduced or prevented.

In addition, the electrode finger duty D and the normalized film thickness d/p of the IDT electrode 54 preferably satisfy the relationship of formula 2:

$$D \leq 1.75 ( d / p ) + 0.05 \qquad ( Formula 2 )$$

As a result, the fractional band width of the XBAR can be about 17% or less with certainty, and inclusion of the spurious response of the high-order mode in the pass band can be prevented.

In addition, the piezoelectric film 53 is preferably made of, for example, lithium niobate or lithium tantalate, and the Euler angles (θ1, θ2, θ3) of the lithium niobate or lithium tantalate of the piezoelectric film 53 preferably fall within the ranges defined by formulas 3, 4, 5, or 6:

$$- 10 ° \leq θ1 \leq 10 ° and 0 ° \leq θ2 \leq 20 ° \qquad ( Formula 3 )$$

$$- 10 ° \leq θ1 \leq 10 ° , 20 ° \leq θ 2 \leq 80 ° , \\ and 0 ° \leq θ3 \leq 60 {° ( 1 - {( θ 2 - 50 )}^{2} / 900 )}^{1 / 2} ) \qquad ( Formula 4 )$$

$$- 10 ° \leq θ1 \leq 10 ° , 20 ° \leq θ2 \leq 80 ° , \\ and [ 180 ° - 60 {° ( 1 - {( θ2 - 50 )}^{2} / 900 )}^{1 / 2} ) ] \leq θ3 \leq 180 ° \qquad ( Formula 5 )$$

$$- 10 ° \leq θ1 \leq 10 ° and \\ [ 180 ° - 30 {° ( 1 - {( θ3 - 90 )}^{2} / 8100 )}^{1 / 2} ) ] \leq θ2 \leq 180 ° \qquad ( Formula 6 )$$

The fractional band width of the acoustic wave resonator 60 can be, for example, about 5% or more by defining the Euler angles of the piezoelectric film 53 including lithium niobate or lithium tantalate as described above.

In the acoustic wave device 1 in the fourth example, an energy confinement layer including a low-acoustic-impedance layer and a high-acoustic-impedance layer may be provided instead of the void 160. Specifically, an energy confinement layer having a structure in which a low-acoustic-impedance layer with relatively low acoustic impedance and a high-acoustic-impedance layer with relatively high acoustic impedance are alternately laminated together may be disposed between the piezoelectric film 53 and the support substrate 51. The energy confinement layer may have a multilayer structure including a low-velocity film and a high-velocity film. The low-velocity film is a film in which the acoustic velocity of a bulk wave in the low-velocity film is smaller than the acoustic velocity of a bulk acoustic wave propagating through the piezoelectric film 53. The high-velocity film is a film in which the acoustic velocity of a bulk wave in the high-velocity film is greater than the acoustic velocity of an acoustic wave propagating through the piezoelectric film 53. Since the normalized film thickness d/p of the piezoelectric film 53 is, for example, about 0.5 or less, and the energy confinement layer is provided, the acoustic wave resonator 60 defines the XBAR.

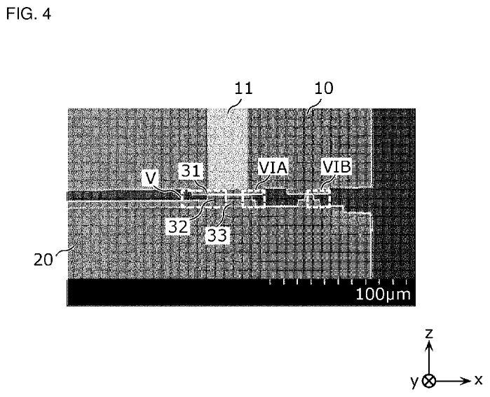

Next, the joint structure of the substrate 10, the via conductor 11, and the metal films 31 to 33 will be described. FIG. 4 is a cross-sectional view illustrating the support portion of the acoustic wave device 1 according to the present example embodiment and surroundings thereof in an enlarged manner. FIG. 4 illustrates a microscopic image of region IV in FIG. 1. As illustrated in FIG. 4, the via conductor 11 is provided in the substrate 10, and the metal film 31 is joined to the lower (Z-axis negative direction) opening portion of the via conductor 11. In addition, the metal film 32, the metal film 33, and the substrate 20 are joined in this order to the Z-axis negative side of the metal film 31.

Here, in plan view of the main surfaces 20a and 10a, the ratio of the area of all of the metal films 31 (see FIG. 2B) disposed on the main surface 10a to the area of the main surface 10a is larger than the ratio of all of the metal films 33 (see FIG. 2A) disposed on the main surface 20a to the area of the main surface 20a.

When the area of the main surface 10a is equal or substantially equal to the area of the main surface 20a, in plan view of the main surfaces 20a and 10a, the total area of all of the metal films 31 (see FIG. 2B) disposed on the main surface 10a is larger than the total area of all of the metal films 33 (see FIG. 2A) disposed on the main surface 20a.

As a result, since the metal films 31 are disposed, at a higher density than the metal films 33 disposed on the main surface 20a, on the main surface 10a that faces the main surface 20a on which the functional electrodes 34 are disposed, noise can be reduced or prevented from being superimposed on a high-frequency signal input and output between the functional electrodes 34 and the via conductors 11. Accordingly, it is possible to provide the acoustic wave device 1 in which degradation of signals of the acoustic wave resonator including the functional electrodes 34 is reduced or prevented.

In addition, the metal films 31 in contact with the main surface 10a can reduce or prevent the stress in a direction (X-axis direction) parallel to the main surface 10a from acting on the substrate 10 in which the via conductors 11 have been provided. In addition, since the wiring line to extract signals from the functional electrodes 34 can also be disposed on the main surface 10a, the degree of freedom in the layout of the functional electrodes 34 on the main surface 20a is improved.

In addition, as illustrated in FIG. 1, thickness Tio of the substrate 10 is smaller than thickness T₂₀ of the substrate 20.

Since the substrate 10 is thinner than the substrate 20, the substrate 10 is more likely to deform due to thermal stress. On the other hand, since the metal films 31 with a relatively high area ratio are provided on the main surface 10a, the metal films 31 can reduce or prevent the stress in the direction (X-axis direction) parallel to the main surface 10a from acting on the substrate 10. Accordingly, the substrate 10 can be reduced or prevented from being cracked or broken by thermal history.

In addition, since the metal films 31 are connected to the metal films 33 and the functional electrodes 34, which are heat sources, through the metal films 32, the metal films 31 can define and function as heat dissipation members, and the heat dissipation capability of the acoustic wave device 1 can be improved.

In addition, as illustrated in FIG. 2B, in plan view of the main surface 10a, the region of the metal film 31 (in the upper right in FIG. 2B) includes the region of the via conductor 11 (in the upper right in FIG. 2B), and the area of the metal film 31 (in the upper right in FIG. 2B) is larger than the area of the via conductor 11 (in the upper right in FIG. 2B).

In other words, in a cross-section (cross-section taken along line I-I in FIGS. 2A to 2C), in a direction (Z-axis direction) orthogonal to the main surface 10a, that passes through the via conductor 11, length L₃₁ of the metal film 31 is greater than length D₁₁ (diameter) of the via conductor 11.

When the region of the metal film 31 is included in the region of the via conductor 11 in plan view of the main surface 10a, the compressive stress of the metal film 31 acts on the via conductor 11, and the via conductor 11 may deform or the via conductor 11 may peel off from the substrate 10. On the other hand, in the structure of the acoustic wave device 1 according to the present example embodiment, in plan view of the main surface 10a, the region of the via conductor 11 is included in the region of the metal film 31, and the area of the metal film 31 is larger than the area of the via conductor 11. As a result, since the substrate 10 adjacent to the via conductor 11 in the X-axis direction is joined to the metal film 31, the substrate 10 joined to the metal film 31 absorbs the compressive stress of the metal film 31 and can reduce or prevent the via conductor 11 from deforming and peeling off. In other words, the fixation of the via conductor 11 can be improved.

In addition, as illustrated in FIG. 2B, in plan view of the main surface 10a, the region of the metal film 32 (in the upper right in FIG. 2B) includes the region of the via conductor 11 (in the upper right in FIG. 2B), and the area of the metal film 32 (in the upper right in FIG. 2B) is larger than the area of the via conductor 11 (in the upper right in FIG. 2B).

In other words, in the cross-section (cross-section taken along line I-I in FIGS. 2A to 2C), in the direction (Z-axis direction) orthogonal to the main surface 10a, that passes through the via conductor 11, length L₃₂ of the metal film 32 is greater than length D₁₁ (diameter) of the via conductor 11.

As a result, since the metal film 32 is joined to the metal film 33, and the metal film 33 is joined to the substrate 20, the compressive stress generated in the metal films 31 and 32 can be distributed to a substrate 20 side as well. Accordingly, the joint strength of the via conductor 11 can be further improved.

It should be noted that “region A includes region B” in this specification means that the entirety of region B is disposed within region A.

In addition, as illustrated in FIG. 2B, in plan view of the main surface 10a, the region of the metal film 31 (in the upper right in FIG. 2B) includes the region of the metal film 32 (in the upper right in FIG. 2B), and the area of the metal film 31 (in the upper right in FIG. 2B) is larger than the area of the metal film 32 (in the upper right in FIG. 2B).

In other words, in the cross-section (cross-section taken along line I-I in FIGS. 2A to 2C), in the direction (Z-axis direction) orthogonal to the main surface 10a, that passes through the via conductor 11, length L₃₁ of the metal film 31 is greater than length L₃₂ of the metal film 32.

As a result, since the joint of the metal film 32 does not deform the shape of the end portion of the metal film 31, the joint between the substrate 10 and the metal film 31 can improve the reduction in the compressive stress acting on the via conductor 11.

In addition, in plan view of the main surface 20a, the region of the metal film 33 includes the region of the metal film 32, and the area of the metal film 33 is larger than the area of the metal film 32.

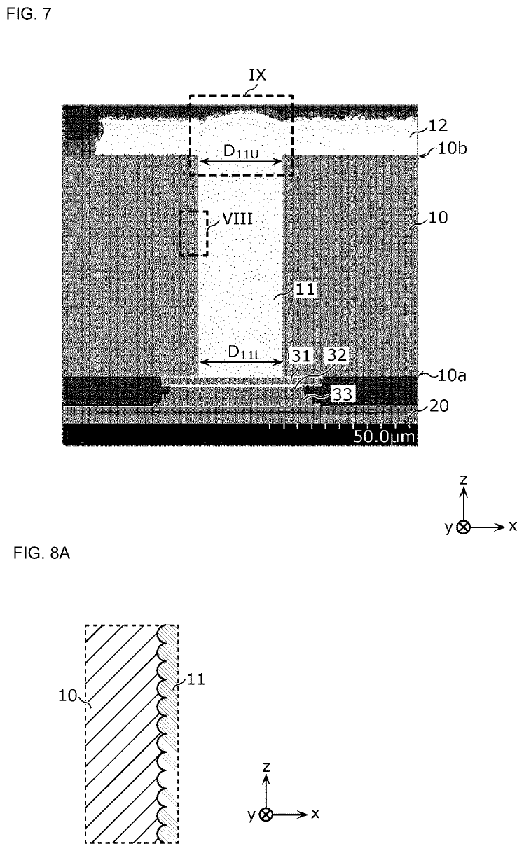

In other words, in the cross-section (cross-section taken along line I-I in FIGS. 2A to 2C, see FIG. 7), in a direction (Z-axis direction) orthogonal to the main surface 20a, that passes through the via conductor 11, length L₃₃ of the metal film 33 is greater than length L₃₂ of the metal film 32.

As a result, since the metal film 32 does not restrict the arrangement regions of the functional electrode 34 and the metal film 33 on the main surface 20a, the layout of the functional electrode 34 and the metal film 33 can be improved.

Next, the multilayer structures of the metal films 31 to 33 will be described. FIG. 5 is a cross-sectional view illustrating examples of the multilayer structures of the metal films 31 to 33 of the acoustic wave device 1 according to the present example embodiment. FIG. 5 is a cross-sectional view schematically illustrating region V in FIG. 4 in an enlarged manner.

As illustrated in FIG. 5, the metal film 31 includes an intermediate layer 316, an intermediate layer 315, a main electrode layer 314, an intermediate layer 313, an intermediate layer 312, and a joint layer 311 in order from a main surface 10a side.

The intermediate layer 313 (first intermediate layer) and the intermediate layer 316 are metal layers including, for example, titanium (Ti) as a main component and define and function as diffusion barrier layers.

The intermediate layer 312 and the intermediate layer 315 are metal layers including, for example, platinum (Pt) as a main component and define and function as diffusion barrier layers together with the intermediate layers 313 and 316.

The main electrode layer 314 is an example of the first main electrode layer, is a metal layer including, for example, aluminum (Al) and copper (Cu) as main components, and defines and functions as a main medium through which a high-frequency signal is transmitted in the metal film 31.

The joint layer 311 is an example of the first joint layer, is a metal layer including, for example, gold (Au) as a main component, and provides a good electrical and mechanical joint with the metal film 32.

The intermediate layers 312 and 315 may be absent in the metal film 31 according to an example embodiment. In addition, the metal film 31 may include only the main electrode layer 314.

In addition, as illustrated in FIG. 5, the metal film 32 includes a joint layer 321, an intermediate layer 322, an intermediate layer 323, a main electrode layer 324, and an intermediate layer 325 in order from the main surface 10a side.

The joint layer 321 is an example of the second joint layer, is a metal layer including, for example, gold (Au) as a main component, and provides a good electrical and mechanical joint with the metal film 31.

The intermediate layer 322 is a metal layer including, for example, platinum (Pt) as a main component and defines and functions as a diffusion barrier layer together with the intermediate layer 323.

The intermediate layer 323 (second intermediate layer) and the intermediate layer 325 are metal layers including, for example, titanium (Ti) as a main component and define and function as diffusion barrier layers.

The main electrode layer 324 is an example of the second main electrode layer, is a metal layer including, for example, aluminum (Al) and copper (Cu) as main components, and defines and functions as a main medium through which a high-frequency signal is transmitted in the metal film 32.

The intermediate layer 322 may be absent in the metal film 32 according to an example embodiment. In addition, the metal film 32 may include only the main electrode layer 324.

In addition, as illustrated in FIG. 5, the metal film 33 includes an intermediate layer 331, a main electrode layer 332, and an intermediate layer 333 in order from the main surface 10a side.

The intermediate layers 331 and 333 are metal layers including, for example, titanium (Ti) as a main component and define and function as diffusion barrier layers.

The main electrode layer 332 is a metal layer including, for example, aluminum (Al) and copper (Cu) as main components and defines and functions as a main medium through which a high-frequency signal is transmitted in the metal film 33.

The intermediate layers 331 and 333 may be absent in the metal film 33 according to an example embodiment, and the metal film 33 may include only the main electrode layer 332.

The main electrode layer 332 in FIG. 5 corresponds to, for example, the main electrode layer 542 in FIG. 3A, and the intermediate layer 333 in FIG. 5 corresponds to, for example, the close contact layer 540 in FIG. 3A.

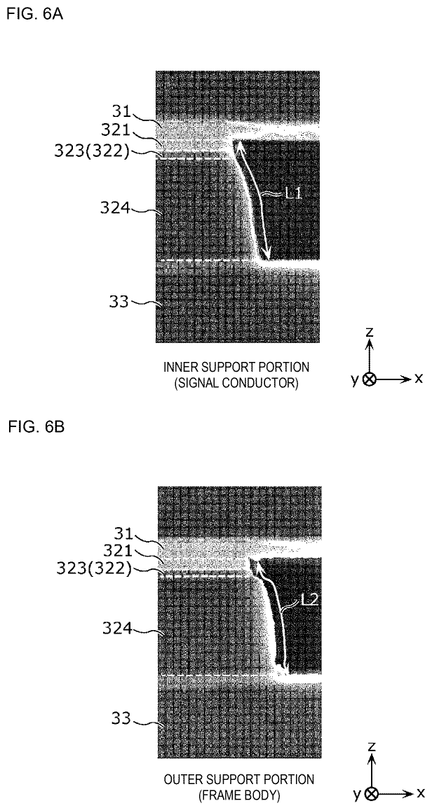

The magnitude relationship of the areas (and the lengths) of the metal layers of each of the metal films is not limited to the magnitude relationship of the areas (and the lengths) of the metal layers illustrated in FIG. 5. The magnitude relationship of the areas (and lengths) of the metal layers will be described with reference to FIGS. 6A and 6B.

Next, the detailed joint state of the metal films of the support portion will be provided. FIG. 6A is a cross-sectional view of an inner support portion according to an example embodiment of the present invention. FIG. 6B is a cross-sectional view of an outer support portion according to the present example embodiment. FIG. 6A illustrates an enlarged microscopic image of region VIA in FIG. 4, and FIG. 6B illustrates an enlarged microscopic image of region VIB in FIG. 4.

FIG. 6A illustrates a cross-sectional view of the first support portion of the plurality of support portions of the acoustic wave device 1 that is a signal conductor through which a signal of the acoustic wave device 1 is transmitted in plan view of the substrates 10 and 20. In addition, FIG. 6B illustrates a cross-sectional view of the second support portion of the support portions of the acoustic wave device 1 that is a frame body surrounding the first support portion and the functional electrodes 34 in plan view of the substrates 10 and 20.

The first support portion illustrated in FIG. 6A is joined to the via conductor 11 and transmits high-frequency (HOT) signals or a ground signal that passes through the functional electrode 34. On the other hand, the second support portion illustrated in FIG. 6B is disposed at the outer edge of the acoustic wave device 1 as a side wall of the acoustic wave device 1 to ensure a space and a region for the functional electrodes 34 and the metal films 33 on the main surface 20a and does not transmit high-frequency (HOT) signals.

In the multilayer structures of the metal films illustrated in FIGS. 6A and 6B, the intermediate layers 323 and 322 are represented as a single layer (intermediate layer 323 (322)). In addition, the intermediate layer 322 may be absent.

In both of FIGS. 6A and 6B, in plan view of the main surface 10a, the region of the metal film 31 includes the region of the metal film 32, and the area of the metal film 31 is larger than the area of the metal film 32. In addition, in plan view of the main surface 10a, the region of the intermediate layer 323 (322) includes the region of the joint layer 321, and the area of the intermediate layer 323 (322) is larger than the area of the joint layer 321. In addition, in plan view of the main surface 10a, the region of the main electrode layer 324 includes the region of the intermediate layer 323 (322), and the area of the main electrode layer 324 is larger than the area of the intermediate layer 323 (322).

As illustrated in FIG. 4, the first support portion includes the metal film 31 in contact with the via conductor 11 and the metal film 32 in contact with the metal film 31, and the second support portion includes the metal film 31 not in contact with the via conductor 11 and the metal film 32 in contact with the metal film 31.

Here, length L2 of the side surface of the metal film 32 in a cross-section of the second support portion (outer support portion) cut in a direction orthogonal to the main surfaces 10a and 20a, which is illustrated in FIG. 6B, is greater than length L1 of the side surface of the metal film 32 in a cross-section of the first support portion (inner support portion) cut in the direction described above, which is illustrated in FIG. 6A.

In the structure described above, when the first support portion and the second support portion are pressure-bonded to each other in the same process, the compression of the metal film 32 in the second support portion with a relatively high pressure-density in the metal film 32 is higher, and the side surface at the end portion is curved. Accordingly, the length of the side surface of the main electrode layer 324 that defines the metal film 32 in the second support portion (L2) is greater than that in the first support portion (L1). As a result, resistance heat generation at the side wall in the first support portion with a smaller side surface at the end portion is further reduced or prevented than in the second support portion, joint failure of the first support portion due to thermal degradation can be reduced or prevented, and the deterioration of a signal passing through the first support portion can be reduced or prevented. On the other hand, the second support portion may be in contact with a resin member disposed at the outer periphery of the acoustic wave device 1. In this case, since the area of the side surface of the main electrode layer 324 is relatively large, the adhesiveness with the resin member is improved, and the heat dissipation to the periphery of the acoustic wave device 1 is also improved.

In comparison of the lengths of the side surfaces of the metal films 32 in the cross-sections in the first support portion and the second support portion, the corners of the second support portion (frame body) in plan view are excluded.

Next, the joint state of the via conductor 11 will be described. FIG. 7 is a cross-sectional view illustrating the via conductor 11 of the acoustic wave device 1 according to the present example embodiment and surroundings thereof in an enlarged manner. FIG. 7 illustrates an enlarged microscopic image of region VII in FIG. 1.

As illustrated in FIG. 7, diameter D_{11L} of the via conductor 11 near the main surface 10a is, for example, at least about 0.9 times and at most about 1.1 times diameter D_{11U} of the via conductor 11 near the main surface 10b.

As a result, since the diameter of the via conductor 11 near the main surface 10a is the same or substantially the same as the diameter of the via conductor 11 near the main surface 10b, stress does not concentrate on only one of the portion of the via conductor 11 near the main surface 10a and the portion of the via conductor 11 near the main surface 10b, stress evenly acts on the portion of the via conductor 11 near the main surface 10a and the portion of the via conductor 11 near the main surface 10b. Accordingly, the via conductor 11 can be reduced or prevented from peeling off from the substrate 10.

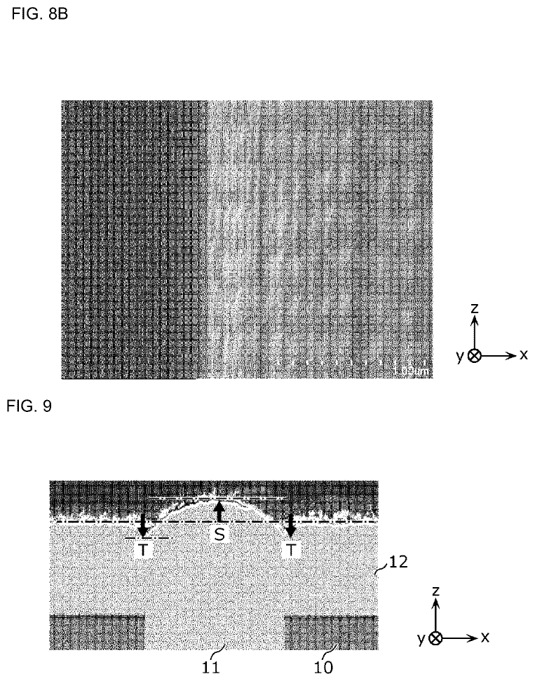

FIG. 8A is a schematic cross-sectional view illustrating the interface between the via conductor 11 and the substrate 10 of the acoustic wave device 1 according to the present example embodiment. FIG. 8B illustrates a SEM image of the interface between the via conductor 11 and the substrate 10 of the acoustic wave device 1 according to the present example embodiment. FIG. 8A is a cross-sectional view schematically illustrating a region VIII in FIG. 7 in an enlarged manner.

In the process of forming, for example, in the substrate 10 made of Si, a cylindrical cavity that is filled with the via conductor 11, a conchoidal uneven structure known as a scallop is formed on the inner wall of the cylindrical cavity of the substrate 10. In the scallop uneven structure, when the tips of convex portions become acute, the electrical resistance at the tips of the uneven structure increases and heat generation is likely to occur, thus reducing the joint strength of the via conductor 11.

In the acoustic wave device 1 according to the present example embodiment, the peak-to-valley (PV) value of the scallop uneven structure is preferably, for example, about 20 μm or less. The PV value is defined as the height difference between the highest point of the tips of the convex portions and the lowest point of the valleys of the concave portions of the uneven structure. In the acoustic wave device 1 according to the present example embodiment, as illustrated in FIGS. 8A and 8B, the tips of the convex portions of the scallop uneven structure are flattened. As a result, since heating can be reduced or prevented by reducing the electrical resistance at the tips of the uneven structure, and the generation of voids at the interface between the via conductor 11 and the substrate 10 can be reduced or prevented, the joint strength of the via conductor 11 can be improved.

FIG. 9 is a cross-sectional view of the planar electrode 12 disposed at an opening portion of the via conductor 11 of the acoustic wave device 1 according to the present example embodiment. FIG. 9 illustrates an enlarged microscopic image of region IX in FIG. 7. The planar electrode 12 is an example of the third planar electrode, is disposed on the main surface 10b, and is in contact with the via conductor 11.

As illustrated in FIG. 9, the planar electrode 12 includes a raised portion S provided in the longitudinal direction (Z-axis direction) of the via conductor 11 and a groove portion T provided at the outer periphery of the raised portion S.

As a result, when the bump electrodes 40 illustrated in FIG. 1 are made of solder or the like, the bump electrodes 40 are more likely to be formed in the raised portion S and the groove portion T during the reflow process, and the positional accuracy of the bump electrodes 40 on the planar electrode 12 is improved.

In the acoustic wave device 1 according to the present example embodiment, for example, only silicon and silicon dioxide may be present, and the metal films may be absent at the end portions and on the side surfaces of the substrate 10.

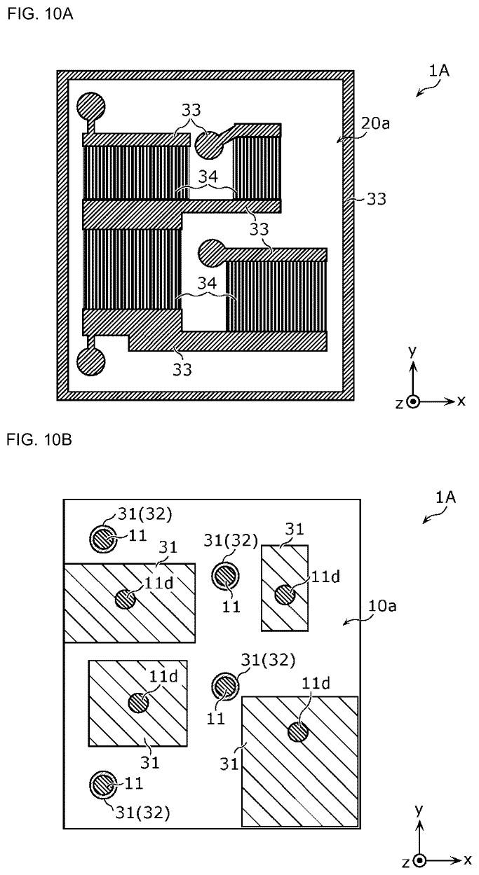

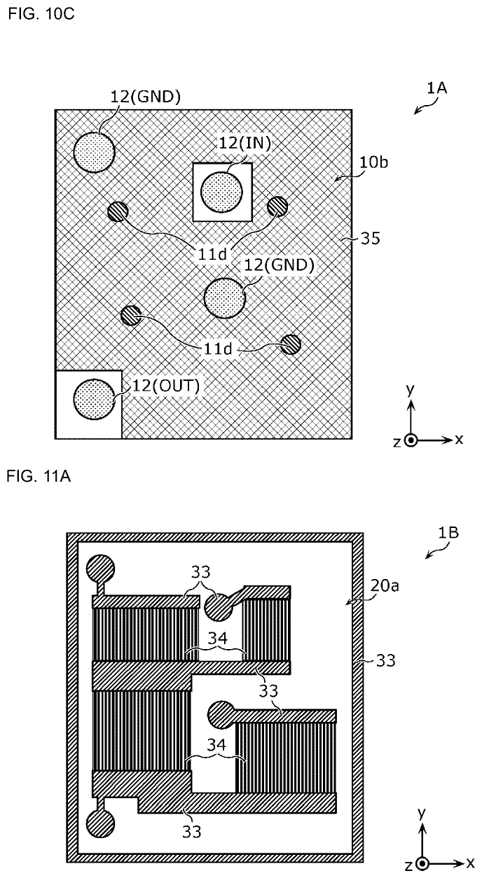

Next, a joint structure of an acoustic wave device 1A according to modification 1 of an example embodiment of the present invention will be described. FIG. 10A is a first plan view of the acoustic wave device 1A according to modification 1. FIG. 10B is a second plan view of the acoustic wave device 1A according to modification 1. FIG. 10C is a third plan view of the acoustic wave device 1A according to modification 1. The cross-sectional structure of the acoustic wave device 1A is the same or substantially the same as the cross-sectional structure of the acoustic wave device 1 illustrated in FIG. 1. FIG. 10A is a plan view (transparent view) of the main surface 20a of the substrate 20 as viewed from the Z-axis positive side, FIG. 10B is a plan view (transparent view) of the main surface 10a of the substrate 10 as viewed from the Z-axis positive side, and FIG. 10C is a plan view of the main surface 10b of the substrate 10 as viewed from the Z-axis positive side. The acoustic wave device 1A includes the substrates 10 and 20, the metal films 31, 32, 33, and 35, the functional electrodes 34, the via conductors 11, a via conductors 11d, the insulation films 13 and 23, the planar electrodes 12, and the bump electrodes 40. The acoustic wave device 1A according to the present modification differs from the acoustic wave device 1 according to the above-described example embodiment mainly in the addition of the via conductors 11d and the metal film 35 and the arrangement layout of the metal film 31. The components of the acoustic wave device 1A according to the present modification that are the same or substantially the same as those of the acoustic wave device 1 according to the above-described example embodiment will not be described below with a focus on different components.

The via conductors 11 are examples of the first via conductor and are disposed in the substrate 10 from the main surface 10a toward the main surface 10b and are connected to the functional electrodes 34 via the metal films 31 to 33 as illustrated in FIGS. 10A and 10B. That is, the via conductors 11 are joined to the support portion including the metal films 31 to 33.

The via conductors 11d are examples of the second via conductor, are disposed in the substrate 10 from the main surface 10a toward the main surface 10b, and are connected to the metal films 31 without being connected to the metal films 32 and 33 as illustrated in FIGS. 10A and 10B. That is, the via conductors 11d are dummy via conductors that are not connected to the metal films 32 and 33 that define the support portion.

The insulation film 13 is, for example, a silicone oxide film and reduces or prevents the leakage of a high-frequency signal between adjacent planar electrodes 12 on the main surface 10b.

The metal film 35 is an example of the fourth metal film, is disposed on the opposite side of the insulation film 13 from the main surface 10b, and is connected to the ground.

As illustrated in FIG. 10C, the via conductors 11d are connected to the metal film 35 on the main surface 10b and are connected to the ground. In addition, one (the third via conductor, which is the via conductor 11 in the upper right in FIG. 10B) of the plurality of via conductors 11 is disposed in a region on the main surface 10b in which the metal film 35 is not provided and is connected to the planar electrode 12 (IN) that is not connected to the metal film 35. In addition, another (the third via conductor, which is the via conductor 11 in the lower left in FIG. 10B) of the via conductors 11 is disposed in a region on the main surface 10b in which the metal film 35 is not provided and is connected to the planar electrode 12 (OUT) that is not connected to the metal film 35. In addition, two other via conductors 11 (the fourth via conductors, which are via conductors 11 in the lower right and the upper left in FIG. 10B) are connected to the planar electrode 12 (GND) that is connected to the metal film 35 on the main surface 10b.

In the structure described above, since the via conductors 11 through which a high-frequency signal is input to and output from the functional electrodes 34 are connected to the metal film 33 on the main surface 20a in the shortest path through the metal films 32 and 31, a high-frequency signal can be transmitted with low loss. In addition, since the dummy via conductors 11d are not connected to the metal films 32 and 33, the dummy via conductors 11d can be disposed without the electrode layout on the main surface 20a being restricted.

In addition, since the metal film 35 is provided on the insulation film 13, the via conductors 11 and 11d connected to the ground can be prevented from being charged on the main surface 10b.

In addition, in plan view of the main surfaces 10a and 20a, the metal film 31 overlaps at least a portion of the functional electrode 34.

As a result, since the metal film 31 connected to the ground is disposed in the region on the main surface 10a that overlaps the functional electrode 34 in plan view of the main surfaces 10a and 20a, noise can be reduced or prevented from being superimposed on a high-frequency signal input and output between the functional electrode 34 and the via conductor 11. Accordingly, it is possible to provide the acoustic wave device 1A in which degradation of signals of the acoustic wave resonator including the functional electrode 34 is reduced or prevented.

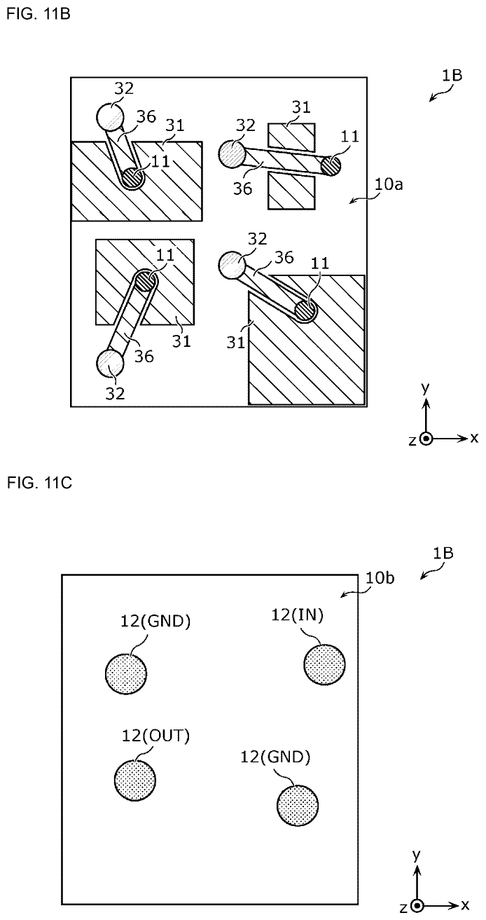

Next, the joint structure of an acoustic wave device 1B according to modification 2 of an example embodiment of the present invention will be described. FIG. 11A is a first plan view of the acoustic wave device 1B according to modification 2. FIG. 11B is a second plan view of the acoustic wave device 1B according to modification 2. FIG. 11C is a third plan view of the acoustic wave device 1B according to modification 2. The cross-sectional structure of the acoustic wave device 1B is the same or substantially the same as the cross-sectional structure of the acoustic wave device 1 illustrated in FIG. 1. FIG. 11A is a plan view (transparent view) of the main surface 20a of the substrate 20 as viewed from the Z-axis positive side, FIG. 11B is a plan view (transparent view) of the main surface 10a of the substrate 10 as viewed from the Z-axis positive side, and FIG. 11C is a plan view of the main surface 10b of the substrate 10 as viewed from the Z-axis positive side. The acoustic wave device 1B includes the substrates 10 and 20, the metal films 31, 32, and 33, a metal film 36, the functional electrodes 34, the via conductors 11, the insulation films 13 and 23, the planar electrodes 12, and the bump electrodes 40. The acoustic wave device 1B according to the present modification differs from the acoustic wave device 1 according to the above-described example embodiment mainly in the addition of the metal film 36 and the arrangement layout of the metal films 31. The components of the acoustic wave device 1B according to the present modification that are the same or substantially the same as those of the acoustic wave device 1 according to the above-described example embodiment will not be described below with a focus on different components.

The metal films 36 are examples of the first metal film and are planar electrodes, in contact with the via conductors 11, that are disposed on the main surface 10a as illustrated in FIG. 11B. The metal film 36 is, for example, a multilayer body including a plurality of metal layers.

The metal films 31 are planar electrodes disposed on the main surface 10a, as illustrated in FIGS. 1 and 11B. The metal film 31 is, for example, a multilayer body including a plurality of metal layers.

The metal films 32 are examples of the third metal film and are planar electrodes in contact with the metal films 36 as illustrated in FIGS. 1 and 11B. The metal film 32 is, for example, a multilayer body including a plurality of metal layers.

The metal films 33 are examples of the second metal film and are planar electrodes that are disposed on the main surface 20a, connected to the functional electrodes 34, and in contact with the metal films 32 as illustrated in FIGS. 1 and 11A. The metal film 33 is, for example, a multilayer body including a plurality of metal layers.

The metal films 36, 32, and 33 define the support portion and are laminated and disposed in this order between the main surface 10a and the main surface 20a so as to provide a space between the main surface 10a and the main surface 20a.

The metal films 31 are not connected to the via conductors 11 as illustrated in FIG. 11B and are not set to a specific potential (floating state).

As a result, since the metal film 31 is disposed in a region on the main surface 10a that overlaps the functional electrode 34 in plan view of the main surfaces 10a and 20a, the electromagnetic field generated by the functional electrode 34 and other wiring lines can be reduced or prevented by the metal film 31, and noise can be reduced or prevented from being superimposed on a high-frequency signal input and output between the functional electrode 34 and the via conductor 11. Accordingly, it is possible to provide the acoustic wave device 1B in which degradation of signals of the acoustic wave resonator including the functional electrode 34 is reduced or prevented.

The metal film 31 may be connected to a conductive side wall (support portion) disposed at the outer periphery of the acoustic wave device 1B or may be connected to the ground.

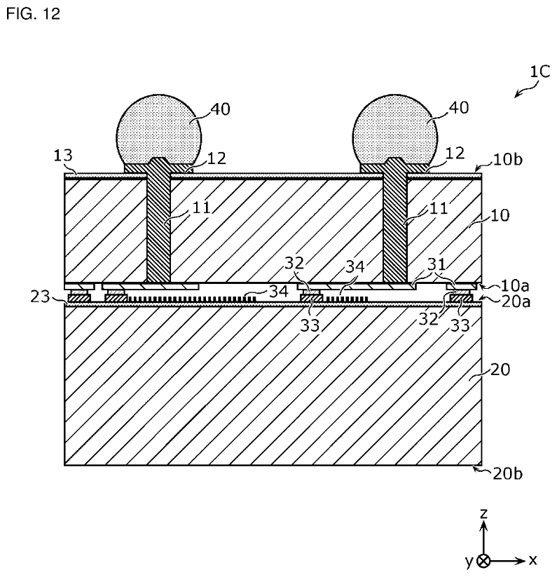

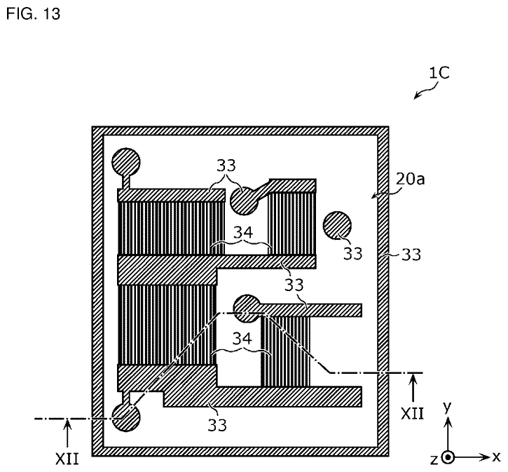

FIG. 12 is a cross-sectional view of an acoustic wave device 1C according to modification 3 of an example embodiment of the present invention. FIG. 13 is a first plan view of the acoustic wave device 1C according to modification 3. FIG. 13 is a plane view (transparent view) of the main surface 20a of the substrate 20 as viewed from the Z-axis positive side. In the acoustic wave device 1C, the plan view (transparent view) of the main surface 10a of the substrate 10 as viewed from the Z-axis positive side is the same or substantially the same as the second plan view in FIG. 2B, and the plan view of the main surface 10b of the substrate 10 as viewed from the Z-axis positive side is the same or substantially the same as the third plan view in FIG. 2C. FIG. 12 is a cross-sectional view taken along line XII-XII in FIG. 13.

As illustrated in FIGS. 12 and 13, the acoustic wave device 1C includes the substrates 10 and 20, the metal films 31, 32, and 33, the functional electrodes 34, the via conductors 11, the insulation films 13 and 23, the planar electrodes 12, and the bump electrodes 40. The acoustic wave device 1C according to the present modification differs from the acoustic wave device 1 according to the above-described example embodiment in the arrangement of the via conductors 11 and the metal films 31, 32, and 33. The components of the acoustic wave device 1C according to the present modification that are the same or substantially the same as those of the acoustic wave device 1 according to the above-described example embodiment will not be described below with a focus on different components.

The metal films 31 are examples of the first metal film and are planar electrodes, in contact with the via conductors 11, that are disposed on the main surface 10a as illustrated in FIG. 12. The metal film 31 is, for example, a multilayer body including a plurality of metal layers.

The metal films 32 are examples of the third metal film and are planar electrodes in contact with the metal films 31 as illustrated in FIG. 12. The metal film 32 is, for example, a multilayer body including a plurality of metal layers.

The metal films 33 are examples of the second metal film and are planar electrodes that are disposed on the main surface 20a, connected to the functional electrodes 34, and in contact with the metal films 32 as illustrated in FIGS. 12 and 13. The metal film 33 is, for example, a multilayer body including a plurality of metal layers.

The functional electrodes 34 are disposed on the main surface 20a and perform electromechanical transduction together with the substrate 20.

As illustrated in FIG. 12, the metal films 31, 32, and 33 constitute the support portion and are laminated and disposed in this order between the main surface 10a and the main surface 20a so as to provide a space between the main surface 10a and the main surface 20a.

In FIG. 12, the right via conductor 11 of the two via conductors 11 does not overlap the functional electrode 34 in plan view of the main surfaces 10a and 20a.

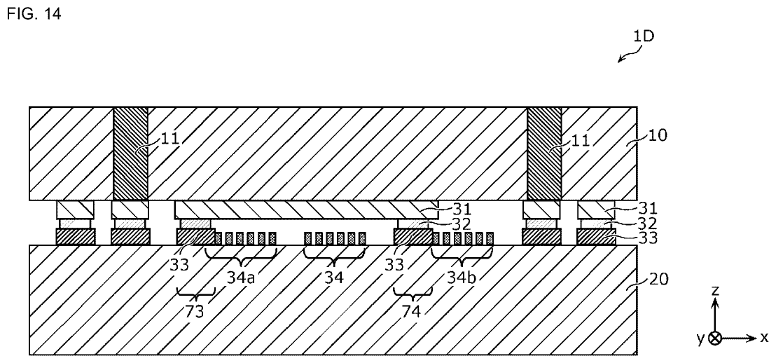

FIG. 14 is a cross-sectional view of an acoustic wave device 1D according to modification 4 of an example embodiment of the present invention. As illustrated in FIG. 14, the acoustic wave device 1D includes the substrates 10 and 20, the metal films 31, 32, and 33, the functional electrodes 34, and the via conductors 11. The acoustic wave device 1D according to the present modification differs from the acoustic wave device 1 according to the above-described example embodiment in the structures of the support portion 73 and 74. The components of the acoustic wave device 1D according to the present modification that are the same or substantially the same as those of the acoustic wave device 1 according to the above-described example embodiment will not be described below with a focus on different components.

The support portion 73 is an example of the third support portion and includes the metal film 31 disposed on the main surface 10a, the metal film 33 disposed on the main surface 20a, and the metal film 32 disposed between the metal films 31 and 33. The support portion 73 is connected to a functional electrode 34a (first functional electrode) on the main surface 20a.

The support portion 74 is an example of the fourth support portion and includes the metal film 31 disposed on the main surface 10a, the metal film 33 disposed on the main surface 20a, and the metal film 32 disposed between the metal films 31 and 33. The support portion 74 is connected to a functional electrode 34b (second functional electrode) on the main surface 20a.

The metal film 31 of the support portion 73 and the metal film 31 of the support portion 74 are integrated with each other, and the support portion 73 and the support portion 74 are connected to each other through the metal film 31 (first wiring line). As a result, the functional electrode 34a and the functional electrode 34b are connected to each other through the metal film 31 disposed on the main surface 10a.

For example, when the functional electrode 34 not connected to the functional electrodes 34a and 34b is disposed between the functional electrodes 34a and 34b, if an attempt is made to provide a wiring line connecting the functional electrode 34a and the functional electrode 34b to each other on the main surface 20a, the wiring line becomes long, and the acoustic wave device becomes large. On the other hand, since the wiring line connecting the functional electrode 34a and the functional electrode 34b to each other is disposed on the main surface 10a in the acoustic wave device 1D according to the present modification, the wiring line can be shortened, and the size of the acoustic wave device 1D can be reduced.

As described above, the acoustic wave device 1 according to an example embodiment of the present invention includes the substrate 10 including the main surfaces 10a and 10b that face away from each other, the substrate 20 including the main surface 20a that faces the main surface 10a, the functional electrodes 34 on the main surface 20a, the support portion between the main surface 10a and the main surface 20a to provide a space between the main surface 10a and the main surface 20a, and the via conductors 11 in the substrate 10 and extending from the main surface 10a toward the main surface 10b, in which the support portion includes the metal films 31 on the main surface 10a and the metal films 33 on the main surface 20a and connected to the functional electrodes 34, and, in plan view of the main surfaces 10a and 20a, the ratio of the area of the metal films 31 to the area of the main surface 10a is larger than the ratio of the area of the metal films 33 to the area of the main surface 20a.

As a result, since the metal films 31 are provided, at a higher density than the metal films 33 provided on the main surface 20a, on the main surface 10a that faces the main surface 20a on which the functional electrodes 34 are disposed, noise can be reduced or prevented from being superimposed on a high-frequency signal input and output between the functional electrodes 34 and the via conductors 11. Accordingly, it is possible to provide the acoustic wave device 1 in which degradation of signals of the acoustic wave resonator including the functional electrodes 34 is reduced or prevented. In addition, the metal films 31 in contact with the main surface 10a can reduce or prevent the stress in the direction (X-axis direction) parallel to the main surface 10a from acting on the substrate 10 in which the via conductors 11 have been provided.

In addition, for example, in the acoustic wave device 1, the substrate 10 is thinner than the substrate 20.

Since the substrate 10 is thinner than the substrate 20, the substrate 10 is more likely to deform due to thermal stress. On the other hand, since the metal films 31 with a relatively high area ratio are provided on the main surface 10a, the metal films 31 can reduce or prevent the stress in the direction (X-axis direction) parallel to the main surface 10a from acting on the substrate 10. Accordingly, the substrate 10 can be reduced or prevented from being cracked or broken by thermal history.

In addition, the acoustic wave device 1A according to modification 1 includes the substrate 10 including the main surfaces 10a and 10b that face away from each other, the substrate 20 including the main surface 20a that faces the main surface 10a, the functional electrodes 34 on the main surface 20a, the support portion between the main surface 10a and the main surface 20a to provide a space between the main surface 10a and the main surface 20a, and the via conductors 11 in the substrate 10 and extending from the main surface 10a toward the main surface 10b, in which the support portion includes the metal films 31 on the main surface 10a and the metal films 33 on the main surface 20a and connected to the functional electrodes 34, and the metal films 31 are connected to the ground through the via conductors 11, and the metal films 31 overlap at least portions of the functional electrodes 34 in plan view of the main surfaces 10a and 20a.

As a result, since the metal film 31 connected to the ground is disposed in a region on the main surface 10a that overlaps the functional electrode 34 in plan view of the main surfaces 10a and 20a, noise can be reduced or prevented from being superimposed on a high-frequency signal input and output between the functional electrode 34 and the via conductor 11. Accordingly, it is possible to provide the acoustic wave device 1A in which degradation of signals of the acoustic wave resonator including the functional electrodes 34 is reduced or prevented.

In addition, for example, in the acoustic wave devices 1 and 1A, the metal film 31 includes the main electrode layer 314, the intermediate layer 313, and the joint layer 311 in order from the main surface 10a side, and the metal film 32 includes the joint layer 321, the intermediate layer 323, and the main electrode layer 324 in order from the main surface 10a side.

As a result, since the metal films 31 and 32 each includes a plurality of metal layers having different functions, a good joint between the metal films 31 and 32 can be achieved.

In addition, for example, in the acoustic wave devices 1 and 1A, the substrate 20 has piezoelectricity, the IDT electrode is provided on the main surface 20a, the IDT electrode includes the plurality of electrode fingers 61a and the plurality of electrode fingers 61b that are arranged in parallel to each other, the busbar electrode 62a that connects one end of each of the plurality of electrode fingers 61a to each other, and the busbar electrode 62b facing the busbar electrode 62a with the plurality of electrode fingers 61a and the plurality of electrode fingers 61b interposed therebetween, that connects one end of each of the plurality of electrode fingers 61b to each other, and the functional electrode 34 includes the plurality of electrode fingers 61a and the plurality of electrode fingers 61b.

In addition, for example, in the acoustic wave device 1, the substrate 20 includes the piezoelectric film 53 including the main surface 20a and the support substrate 51, and d/p is about 0.5 or less where d is the thickness of the piezoelectric film 53 and p is the electrode finger pitch of the IDT electrode 54.

As a result, it is possible to provide an XBAR device in which the joint strength of the support portion is improved.

In addition, for example, in the acoustic wave devices 1 and 1A, the metal film 33 includes the busbar electrodes 62a and 62b.

As a result, it is possible to provide a surface acoustic wave device or an XBAR device in which degradation of signals of the acoustic wave resonator is reduced or prevented.

In addition, for example, in the acoustic wave devices 1 and 1A, the functional electrode 34 includes the lower electrode 66, the piezoelectric layer 67, and the upper electrode 68 in order from the main surface 20a, and the metal film 33 includes the lower electrode 66 and the upper electrode 68.

As a result, it is possible to provide a bulk acoustic wave device in which degradation of signals of a bulk acoustic wave resonator is reduced or prevented.

In addition, for example, in the acoustic wave devices 1 and 1A, the diameter of the via conductor 11 on the main surface 10a is at least about 0.9 times and at most about 1.1 times the diameter of the via conductor 11 on the main surface 10b.

As a result, since the diameter of the via conductor 11 on the main surface 10a is the same or substantially the same as the diameter of the via conductor 11 on the main surface 10b, stress evenly acts on a portion of the via conductor 11 near the main surface 10a and a portion of the via conductor 11 near the main surface 10b. Accordingly, the via conductor 11 can be reduced or prevented from peeling off from the substrate 10.

In addition, for example, the acoustic wave device 1 includes a plurality of support portions, the plurality of support portions each include the metal film 32, in contact with the metal film 31 and the metal film 33, that is provided between the metal films 31 and 33, the region of the metal film 31 includes the region of the metal film 32 and the area of the metal film 31 is larger than the area of the metal film 32 in plan view of the main surface 10a, the first support portion of the plurality of support portions is a signal conductor through which a signal of the acoustic wave device 1 is transmitted, the second support portion of the plurality of support portions is a frame body surrounding the first support portion and the functional electrode 34 in the plan view, and length L2 of the side surface of the metal film 32 in a cross-section obtained by cutting the second support portion in the direction orthogonal to the main surfaces 10a and 20a is greater than length L1 of the side surface of the metal film 32 in a cross-section obtained by cutting the first support portion in the direction.

As a result, when the first support portion and the second support portion are pressure-bonded to each other in the same process, the compression of the metal film 32 in the second support portion with a relatively high pressure-density in the metal film 32 is higher, and the side surface at the end portion is curved. Accordingly, the length of the side surface of the main electrode layer 324 that defines the metal film 32 in the second support portion (L2) is greater than that in the first support portion (L1). As a result, resistance heat generation at the side wall in the first support portion with a smaller side surface at the end portion is further reduced or prevented than in the second support portion, joint failure of the first support portion due to thermal degradation can be reduced or prevented, and the deterioration of a signal passing through the first support portion can be reduced or prevented. On the other hand, the second support portion may be in contact with the resin member disposed at the outer periphery of the acoustic wave device 1. In this case, since the area of the side surface of the main electrode layer 324 is relatively large, the adhesion with the resin member is improved, and the heat dissipation to the periphery of the acoustic wave device 1 is also improved.

In addition, for example, the acoustic wave device 1D according to modification 4 includes the support portions 73 and 74 and the functional electrodes 34a and 34b on the main surface 20a, the support portion 73 is connected to the functional electrode 34a on the main surface 20a, the support portion 74 is connected to the functional electrode 34b on the main surface 20a, and the support portion 73 and the support portion 74 are connected to each other through the metal film 31 on the main surface 10a.

As a result, since the wiring line connecting the functional electrode 34a and the functional electrode 34b to each other is provided on the main surface 10a, the wiring line can be shortened, and the size of the acoustic wave device 1D can be reduced.

In addition, for example, the acoustic wave device 1 further includes the planar electrode 12, in contact with the via conductor 11, that is provided on the main surface 10b, and the planar electrode 12 includes the raised portion S in the longitudinal direction of the via conductor 11 and the groove portion T at the outer periphery of the raised portion S.

As a result, when the bump electrodes 40 are made of solder or the like, the positional accuracy of the bump electrodes 40 on the planar electrodes 12 is improved.

In addition, for example, the acoustic wave device 1A includes the plurality of via conductors, the via conductor 11 of the plurality of via conductors is connected to the functional electrode 34 through the metal films 31 and 33, and the via conductor 11d of the plurality of via conductors is connected to the metal film 31, not connected to the metal film 33, and connected to the ground.

As a result, since the via conductor 11 through which a high-frequency signal is input to and output from the functional electrode 34 is connected to the metal film 33 on the main surface 20a in the shortest path through the metal film 31, a high-frequency signal can be transmitted with low loss. In addition, since the dummy via conductors 11d are not connected to the metal film 33, the dummy via conductors 11d can be arranged without the electrode layout on the main surface 20a being restricted.

In addition, for example, the acoustic wave device 1A includes the plurality of via conductors, the acoustic wave device 1A further includes the insulation film 13 on the main surface 10b and the metal film 35, located on the opposite side of the insulation film 13 from the main surface 10b, that is connected to the ground, the third via conductor of the plurality of via conductors through which high-frequency input signals of the acoustic wave device 1A are transmitted is not connected to the metal film 35 and is located in a region on the main surface 10b in which the metal film 35 is not provided in plan view of the main surface 10b, and the fourth via conductor of the plurality of via conductors to which the ground potential of the acoustic wave device 1A is set is connected to the metal film 35.

As a result, since the metal film 35 is provided on the insulation film 13, the via conductors 11 and 11d connected to the ground can be prevented from being charged on the main surfaces 10b.

In addition, for example, in the acoustic wave device 1, in plan view of the main surface 10a, the region of the metal film 31 includes the region of the via conductor 11, and the area of the metal film 31 is larger than the area of the via conductor 11.

As a result, the substrate 10 adjacent to the via conductor 11 in the X-axis direction is joined to the metal film 31, and the substrate 10 joined to the metal film 31 can absorb the compressive stress of the metal films 31 and 32, and accordingly, the via conductor 11 can be reduced or prevented from deforming and peeling off.

In addition, for example, in the acoustic wave device 1, the region of the metal film 31 includes the region of the metal film 32 and the area of the metal film 31 is larger than the area of the metal film 32 in plan view of the main surface 10a, and the region of the metal film 33 includes the region of the metal film 32, and the area of the metal film 33 is larger than the area of the metal film 32 in plan view of the main surface 20a.

As a result, since the joint of the metal film 32 does not deform the shape of the end portion of the metal film 31, the joint between the substrate 10 and the metal film 31 can improve the reduction in the compressive stress applied to the via conductor 11. In addition, since the metal film 32 does not restrict the arrangement regions of the functional electrode 34 and the metal film 33 on the main surface 20a, the arrangement layout of the functional electrode 34 and the metal film 33 can be improved.

The acoustic wave devices according to the present invention have been described by using example embodiments and modifications, but the present invention is not limited to the example embodiments and the modifications. Modifications obtained by applying various changes conceived by those skilled in the art to the example embodiments and the modifications without deviating from the scope of the present invention and various devices incorporating the acoustic wave devices according to example embodiments of the present invention and modifications are also included in the present invention.

Example embodiments of the present invention are widely applicable as compact acoustic wave devices to communication devices, such as cellular phones, for example.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first substrate including a first main surface and a second main surface facing away from each other;
a second substrate including a third main surface facing the first main surface;
a functional electrode on the third main surface;
a support portion positioned between the first main surface and the third main surface to provide a space between the first main surface and the third main surface; and
a via conductor in the first substrate and extending from the first main surface toward the second main surface; wherein
the support portion includes a first metal film on the first main surface and a second metal film on the third main surface and connected to the functional electrode; and
in plan view of the first main surface and the third main surface, a ratio of an area of the first metal film to an area of the first main surface is larger than a ratio of an area of the second metal film to an area of the third main surface.

2. The acoustic wave device according to claim 1, wherein the first substrate is thinner than the second substrate.

3. An acoustic wave device comprising:
a first substrate including a first main surface and a second main surface facing away from each other;
a second substrate including a third main surface facing the first main surface;
a functional electrode on the third main surface;
a support portion between the first main surface and the third main surface to provide a space between the first main surface and the third main surface; and
a via conductor in the first substrate and extending from the first main surface toward the second main surface; wherein
the support portion includes a first metal film on the first main surface, and a second metal film on the third main surface and connected to the functional electrode;
the first metal film is connected to a ground through the via conductor;
in plan view of the first main surface and the third main surface, the first metal film overlaps at least a portion of the functional electrode.

4. The acoustic wave device according to claim 1, wherein
the first metal film includes a first main electrode layer, a first diffusion barrier layer, and a first joint layer in order from a first main surface side; and
the second metal film includes a second joint layer, a second diffusion barrier layer, and a second main electrode layer in order from the first main surface side.

5. The acoustic wave device according to claim 1, wherein
the second substrate has piezoelectricity;
an interdigital transducer (IDT) electrode is provided on the third main surface;
the IDT electrode includes a plurality of first electrode fingers and a plurality of second electrode fingers parallel or substantially parallel to each other, a first busbar electrode connecting one end of each of the plurality of first electrode fingers to each other, and a second busbar electrode connecting one end of each of the plurality of second electrode fingers to each other and facing the first busbar electrode with the plurality of first electrode fingers and the plurality of second electrode fingers therebetween; and
the functional electrode includes the plurality of first electrode fingers and the plurality of second electrode fingers.

6. The acoustic wave device according to claim 5, wherein
the second substrate includes a support substrate and a piezoelectric film including the third main surface; and
d/p is about 0.5 or less where d is a thickness of the piezoelectric film, and p is an electrode finger pitch of the IDT electrode.

7. The acoustic wave device according to claim 5, wherein the second metal film includes the first busbar electrode and the second busbar electrode.

8. The acoustic wave device according to claim 1, wherein
the functional electrode includes a first planar electrode, a piezoelectric thin film, and a second planar electrode in order from the third main surface; and
the second metal film includes the first planar electrode and the second planar electrode.

9. The acoustic wave device according to claim 1, wherein a diameter of the via conductor on the first main surface is at least about 0.9 times and at most about 1.1 times a diameter of the via conductor on the second main surface.

10. The acoustic wave device according to claim 1, further comprising:
a plurality of support portions, the support portion being one of the plurality of support portions; wherein
each of the plurality of the support portions further includes a third metal film between the first metal film and the second metal film and in contact with the first metal film and the second metal film;
in plan view of the first main surface, a region of the first metal film includes a region of the third metal film, and an area of the first metal film is larger than an area of the third metal film;
a first support portion of the plurality of support portions includes a signal conductor through which a signal of the acoustic wave device is transmitted;
a second support portion of the plurality of support portions includes a frame body surrounding the first support portion and the functional electrode in plan view of the first main surface and the second main surface; and
a length of a side surface of the third metal film in a cross-section obtained by cutting the second support portion in a direction orthogonal to the first main surface and the second main surface is greater than a length of a side surface of the third metal film in a cross-section obtained by cutting the first support portion in orthogonal direction.

11. The acoustic wave device according to claim 1, further comprising:
a plurality of support portions, the support portion being one of the plurality of support portions, and a plurality of functional electrodes on the third main surface, the functional electrode being one of the plurality of functional electrodes;
wherein a third support portion of the plurality of support portions is connected to a first functional electrode of the plurality of functional electrodes on the third main surface;
a fourth support portion of the plurality of support portions is connected to a second functional electrode of the plurality of functional electrodes on the third main surface; and
the third support portion and the fourth support portion are connected to each other through a first wiring line on the first main surface.

12. The acoustic wave device according to claim 1, further comprising:
a third planar electrode in contact with the via conductor and provided on the second main surface; wherein
the third planar electrode includes a raised portion arranged in a longitudinal direction of the via conductor and a groove portion at an outer periphery of the raised portion.

13. The acoustic wave device according to claim 1, further comprising:
a plurality of via conductors, the via conductor being one of the plurality of via conductors; wherein
a first via conductor of the plurality of via conductors is connected to the functional electrode through the first metal film and the second metal film; and
a second via conductor of the plurality of via conductors is connected to the first metal film, not connected to the second metal film, and connected to a ground.

14. The acoustic wave device according to claim 1, further comprising:
a plurality of via conductors, the via conductor being one of the plurality of via conductors;
an insulation film on the second main surface; and
a fourth metal film on an opposite side of the insulation film from the second main surface and is connected to a ground;
wherein a third via conductor of the plurality of via conductors through which a high-frequency input signal of the acoustic wave device is transmitted is not connected to the fourth metal film and, in plan view of the second main surface, is located in a region on the second main surface in which the fourth metal film is not formed; and
a fourth via conductor of the plurality of via conductors to which a ground potential of the acoustic wave device is set is connected to the fourth metal film.

15. The acoustic wave device according to claim 1, wherein, in plan view of the first main surface, a region of the first metal film includes a region of the via conductor, and an area of the first metal film is larger than an area of the via conductor.

16. The acoustic wave device according to claim 10, wherein
in plan view of the first main surface, the region of the first metal film includes the region of the third metal film, and the area of the first metal film is larger than the area of the third metal film; and
in plan view of the third main surface, a region of the second metal film includes the region of the third metal film, and an area of the second metal film is larger than the area of the third metal film.

17. The acoustic wave device according to claim 3, wherein
the first metal film includes a first main electrode layer, a first diffusion barrier layer, and a first joint layer in order from a first main surface side; and
the second metal film includes a second joint layer, a second diffusion barrier layer, and a second main electrode layer in order from the first main surface side.

18. The acoustic wave device according to claim 3, wherein
the second substrate has piezoelectricity;
an interdigital transducer (IDT) electrode is provided on the third main surface;
the IDT electrode includes a plurality of first electrode fingers and a plurality of second electrode fingers parallel or substantially parallel to each other, a first busbar electrode connecting one end of each of the plurality of first electrode fingers to each other, and a second busbar electrode connecting one end of each of the plurality of second electrode fingers to each other and facing the first busbar electrode with the plurality of first electrode fingers and the plurality of second electrode fingers therebetween; and
the functional electrode includes the plurality of first electrode fingers and the plurality of second electrode fingers.

19. The acoustic wave device according to claim 18, wherein
the second substrate includes a support substrate and a piezoelectric film including the third main surface; and
d/p is about 0.5 or less where d is a thickness of the piezoelectric film, and p is an electrode finger pitch of the IDT electrode.

20. The acoustic wave device according to claim 18, wherein the second metal film includes the first busbar electrode and the second busbar electrode.
